(19) United States
(12) Patent Application Publication
(10) Pub. No.: US 2014/0144499 A1
(43) Pub. Date: May 29, 2014

(54) PHOTOVOLTAIC MODULE BACKSHEET HAVING A THERMOPLASTIC POLYOLEFIN COMPOSITE LAYER

(71) Applicant: HONEYWELL INTERNATIONAL, INC., Morristown, NJ (US)

(72) Inventors: Neo Huang, Shanghai (CN); Shuwen Peng, Shanghai (CN); Hongsheng Zhang, Shanghai (CN); Limei Cui, Shanghai (CN)

(73) Assignee: Honeywell International, Inc., Morristown, NJ (US)

(21) Appl. No.: 13/829,827

(22) Filed: Mar. 14, 2013

Related U.S. Application Data
(60) Provisional application No. 61/731,400, filed on Nov. 29, 2012.

(51) Int. Cl. H01L 31/048; H01L 31/18

(52) U.S. Cl. CPC H01L 31/0487; H01L 31/18
USPC 136/256; 264/173.19

(57) ABSTRACT

The present invention relates to backsheets containing formulated thermoplastic polyolefin (TPO) which may be used with photovoltaic modules. More specifically, the backsheets of the present invention have a first exterior layer that comprises TPO and a polyamide, such that a residual fusion heat after lamination of that layer is at least 40 J/g. Using such a layer, sufficient bonding to the encapsulant of a photovoltaic module can be achieved, while maintaining high heat resistance, having low distortion at high operating temperatures, and having relatively low high water vapor transmission rate. The present invention also relates to photovoltaic modules containing the backsheets of the present invention, as well as to methods for making the backsheets of the present invention.

### CROSS REFERENCE TO RELATED APPLICATION

The present application claims the benefit of U.S. Provisional Patent Application No. 61/731,400, filed on Nov. 29, 2012, the disclosure of which is incorporated herein by reference in its entirety.

### FIELD OF THE INVENTION

The present invention relates to backsheets containing formulated thermoplastic polyolefin (TPO) which may be used with photovoltaic modules.

### DESCRIPTION OF RELATED ART

At the present time, composites of fluoropolymers and poly(ethylene terephthalate) (PET) are commonly used for backsheets for photovoltaic modules. For example, a fluoropolymer layer on the outside provides weathering resistance, and the PET in the core layer provides dielectric insulation and mechanical strength. In addition, another layer of fluoropolymer on the other side of a core layer can provide bonding to an encapsulant material in the photovoltaic module, for example, an ethylene vinyl acrylate (EVA) encapsulant.

However, backsheets using fluoropolymers and PET have several drawbacks. First, PET is easily hydrolyzed, and as such, may fail in hot and/or humid conditions. Second, fluoropolymers such as PVF, PVDF or ETFE are difficult to process into films, are expensive, and are subject to constraints in raw material supply. Third, the use of different polymer layers requires an adhesive to bond them together, and this adhesive can potentially fail in long term outdoor use.

As such, a number of alternative backsheet compositions have been investigated for use with photovoltaic modules. For example, EP 2390093, US 2008/0078445, US 2010/0108128, WO 2011/009568, WO 2012/024262, and US 2012/0111407 propose using thermoplastic olefins, including polypropylene and polyethylene based plastics, in backsheet layers. However, such non-polar polypropylenes and polyethylenes typically exhibit low adhesion with EVA encapsulant material in photovoltaic modules. As a result, it is suggested that low-melting-point adhesion material be added, or in the alternative, low-melting-point adhesion material is grafted or copolymerized with the polypropylene or polyethylene. For example, ethylene-propylene copolymer, ethylene propylene diene rubber, ethylene-octene copolymer, ethylene-ethyl acrylate copolymer (EEA), maleic anhydride (MAH) grafted ethylene polymer, ethylene acrylic acid copolymer (EAA), ethylene methyl acrylate (EMA), and ethylene vinyl acrylate (EVA) have been suggested for use, especially in the layer facing the encapsulant.

During module lamination conditions, e.g., at 140-150° C. temperature for about 20 minutes, these low-melting-point compositions melt and interpenetrate with the EVA encapsulant, thus generating adhesion. However, such layers will be vulnerable to heat distortion, thickness variation, unfavorable edge flow, and hence subject to potential degradation of the insulation properties during the module lamination process. Such layers are also exhibit low heat resistance and/or are susceptible to a high degree of distortion at higher photovoltaic module working temperatures.

Other investigated materials do not experience such heat resistance and distortion issues, but have other drawbacks. Both US 2010/0059105 and US 2012/0028060 suggest the use of polyamide compositions for backsheet layers for photovoltaic modules; however, polyamide has relatively high water vapor transmission rate (WVTR), and transmission of water vapor can greatly degrade photovoltaic module performance. While some exotic polyamide grades have relatively high water resistance properties, such materials are expensive and difficult to manufacture. Not surprisingly then, US 2012/0028060 suggests the use of barrier layers to address the water vapor transmission problems encountered when using polyamides.

Accordingly, it is desired to formulate a backsheet layer which has high adhesion to typical photovoltaic module encapsulants such as EVA, yet does not have problems with low heat resistance, distortion at high operating temperatures, and high water vapor transmission rate.

### BRIEF SUMMARY OF THE INVENTION

To address the above issues, new formulated thermoplastic polyolefin layers were developed for use in photovoltaic module backsheets. These formulated TPO layers adhere well to encapsulated photovoltaic modules, yet, in contrast to existing technology, have favorable performance at high operating temperatures and do not have a high water vapor transmission rate.

According to one aspect of the present invention, a backsheet layer contains a TPO material, and a second polymer material, such as polyamide, epoxy, thermoplastic polyurethane (TPU), polyphenylene ether, and polycarbonate, such that a residual fusion heat after lamination at 150° C. of the backsheet layer is at least 40 J/g so as to possess favorable dimensional stability at lamination temperatures. More preferably, the residual fusion heat after lamination at 150° C. of the backsheet layer is at least 50 J/g. Most preferably, the TPO material is polypropylene and the second polymer material is a polyamide.

According to a second aspect of the present invention, the backsheet layer is combined with one or more layers to form a composite backsheet for a photovoltaic module. Preferably, each of the additional layers of the composite backsheet has the same TPO material as the first backsheet layer, such that the layers are chemically affinitive, and therefore require no tie layers or extra adhesive layers between them.

According to a third aspect of the present invention, the backsheet layer contains additives such as compatibilizers, fillers, pigments, UV additives, flame retardants, etc. In addition, or alternatively, these additives can be contained within other backsheet layers of a composite backsheet.

According to a fourth aspect of the present invention, a photovoltaic module contains a TPO backsheet layer or a composite backsheet containing a TPO backsheet layer, such that the TPO backsheet layer which contacts the encapsulant for a photovoltaic module has a residual fusion heat after lamination, e.g., at 150° C., which is at least 40 J/g.

According to a fifth aspect of the present invention, the backsheet layer containing a TPO material and the second polymer material, such as polyamide, epoxy, thermoplastic polyurethane (TPU), polyphenylene ether, and polycarbonate, is formed via an extrusion process.

According to a sixth aspect of the present invention, the backsheet layer is coextruded with other backsheet layers so as to produce a composite backsheet.

According to a seventh aspect of the present invention, at least one layer of a TPO-containing composite backsheet is a weatherable fluoropolymer.

### BRIEF DESCRIPTION OF THE DRAWINGS

Specific examples have been chosen for purposes of illustration and description, and are shown in the accompanying drawings, forming a part of the specification.

FIG. 1 illustrates differential scanning calorimetry (DSC) analysis of a backsheet layer of the present invention.

FIG. 2 illustrates one example of a three layer composite backsheet of the present invention.

### DETAILED DESCRIPTION

In accordance with a first embodiment of the present invention, a backsheet consists of only a single layer, the single layer having both polypropylene polymer and polyamide polymer such that the residual fusion heat after lamination at 150° C. is at least 40 J/g.

Preferably, a backsheet layer containing such a polypropylene polymer would contain at least 35 wt % of the polypropylene polymer; however, preferably, higher amounts such as 50 wt %, 65 wt %, or 70 wt % could be used in conjunction with polyamide polymer to obtain sufficient residual fusion heat after lamination at 150° C. and sufficient bonding to EVA.

Furthermore, while PA6 polyamide is preferred for use as the polyamide component in the layer, different polyamide(s) may be used instead, provided that the polyamide(s) can be compounded together with polypropylene by the help of compatilizers in a certain temperature range such as 210-280° C., and sufficient bonding to the encapsulant of a photovoltaic module can be achieved. Examples of other polyamides which could be used include PA11, PA12, PA13, PA46, PA66, PA610, PA612, PA1010, Nylon MXD6, PA copolymer such as PA6-PA66-PA1010 copolymer, and mixtures thereof. Preferably, a material is selected such that a bonding strength to EVA of at least 40 N/cm is achieved, however, even higher bonding strengths of, e.g., at least 50 N/cm are preferably achieved. To achieve such bonding strength, a layer preferably contains at least 5 wt % polyamide, and more preferably at least 20 wt % polyamide; however, it is contemplated that only a small amount of polyamide, such as 1 or 2 wt %, can achieve adequate bonding for certain applications. Furthermore, it is preferred that polyamide content not exceed 50 wt %, or more preferably 40 wt %, so that the backsheet does not have excessively high water vapor transmission rates, which could lead to degradation of module performance. Most preferably, this backsheet layer has an even higher residual fusion heat after lamination, for example, 50 J/g or higher.

The following table, Table 1, compares examples when varying the main compositions (as measured in wt %) of a layer.

TABLE 1

| | TPO Layer formulation (1^{ST} layer) | | | | Properties | | |
|---|---|---|---|---|---|---|---|
| | | MAH-g- | POE-1 | PA6 | Residual Fusion | Adhe- | |
| | PP | PP | (Engage | (Honey- | Heat after | sion to | |
| Ex. | (HA748L) | (CA100) | 8180) | well 35H) | Lamination⁽²⁾ | EVA⁽³⁾ | WVTR⁽⁴⁾ |
| 1 | 100 | | | | 99.0 | 12.0 | 0.78 |
| 2 | 75 | 5 | 20 | | 56.5 | 25.3 | 0.92 |
| 3 | 60 | | 40 | | 35.0 | 41.1 | 0.91 |
| 4 | 50⁽¹⁾ | | 50 | | 12.7 | 62.0 | 0.93 |
| 5 | 70 | 5 | 20 | 5 | 53.5 | 50.3 | 1.03 |
| 6 | 65 | 5 | 20 | 10 | 53.0 | 62.8 | 1.14 |
| 7 | 55 | 5 | 20 | 20 | 50.1 | 81.3 | 1.20 |
| 8 | 35 | 5 | 20 | 40 | 44.9 | >110 | 1.23 |
| 9 | | | | 100 | 54.24 | >110 | 24.5 |

⁽¹⁾Contains random copolymer propylene.
⁽²⁾Residual fusion heat after lamination at 150° C. in J/g.
⁽³⁾Adhesion to fast-cure EVA (FIRST EVA, F806) in N/cm using ASTM D903.
⁽⁴⁾Backsheet WVTR (in g/m²/day, 0.4 mm thickness, 38° C., 100% relative humidity)

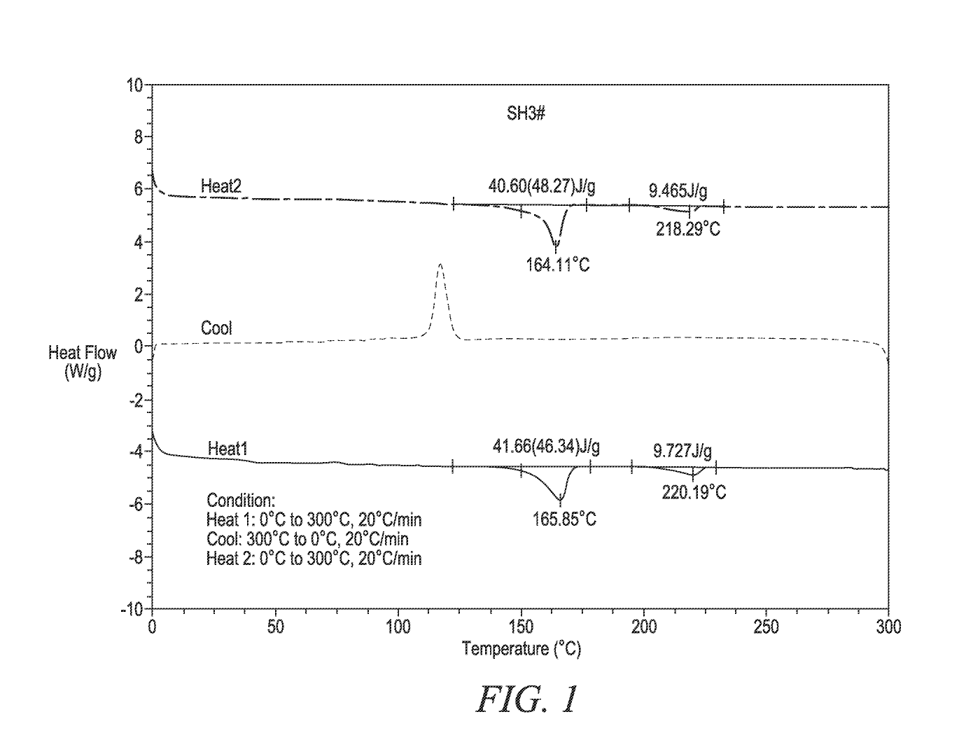

Referring back to Table 1, Example 7 contains a favorable combination of bonding strength, WVTR, and heat resistance properties. As shown in FIG. 1, this layer has a relatively high residual fusion heat after lamination at 150° C. as measured by differential scanning calorimetry (DSC), i.e., 50.1 J/g. It is noted that this DSC experiment runs two heating cycles, separated by a single cooling cycle. Using the data from the second heating cycle, a separation line is drawn, perpendicular to the base line at 150° C. position, and the area portions below the baseline at temperatures above 150° C. are determined (typically, automatically using standard DSC equipment) such that the “residual fusion heat after lamination at 150° C.” is calculated.

Each of the examples of Table 1 was prepared using a conventional extruder compounding process, i.e., the materials and additives were pre-mixed in the specified proportions, and then added through feeders into a twin-screw extruder. For optimum throughput, a temperature range of 220-250° C. was used, and various extruder screw speeds were used depending on the blend. The extruded plastic melt strands were then cooled in a water bath, and then pelletized for film/sheet extrusion process. In the film/sheet extrusion process, the materials were added through feeders into a single-screw extrusion system containing extruders, a die system, a cooling roll system, and sheet winding systems. It has also been found that a conventional multiple extruder co-extrusion system can be used when a backsheet requires multiple layers having different functions. Both compounding and film extrusion processes are known to persons skilled in the relevant art.

In accordance with a second embodiment of the present invention, a backsheet consists of only a single layer, the single layer having both a TPO component and a second polymer component such that the residual fusion heat after lamination at 150° C. is at least 40 J/g and such that the layer has a bonding adhesion to EVA of greater than about 40 N/cm. Preferably, a backsheet layer would contain at least 35 wt % of the TPO component; however, preferably, higher amounts such as 50 wt %, 65 wt %, or 70 wt % could be used in conjunction with a second polymer to obtain sufficient residual fusion heat after lamination at 150° C. and sufficient bonding to EVA. Preferably, a material is selected such that a bonding strength to EVA of at least 40 N/cm is achieved, however, even higher bonding strengths of, e.g., at least 60 N/cm, or even more preferably, at least 80 N/cm are preferably achieved. To achieve such bonding strength, a layer preferably contains at least 5 wt % of the second polymer, and more preferably at least 20 wt % of a second polymer; however, it is contemplated that only a small amount of the second polymer, such as 1 or 2 wt %, can achieve adequate bonding for certain applications. More preferably, this backsheet layer has an even higher residual fusion heat after lamination, for example, 50 J/g or higher.

While the use of polyamide is preferred in accordance with the present invention, in accordance with a third embodiment of the present invention, a combination of high residual fusion heat after lamination and suitable adhesion to EVA can also be achieved through the use of alternative second polymers such as epoxy, thermoplastic polyurethane (TPU), polyphenylene ether, and polycarbonate in conjunction with the TPO components of the previous embodiments. Preferably, a second polymer is selected such that a bonding strength to EVA of at least 40 N/cm is achieved, however, even higher bonding strengths of, e.g., at least 50 N/cm, or even more preferably, at least 80 N/cm are preferably achieved. To achieve such bonding strength, a layer preferably contains at least 5 wt % of the second polymer, and more preferably at least 20 wt % of the second polymer; however, it is contemplated that only a small amount of the second polymer, such as 1 or 2 wt %, can achieve adequate bonding for certain applications.

The following table, Table 2, compares examples when varying the main compositions (as measured in wt %) of a layer.

TABLE 2

| | TPO Layer formulation (1^{ST} layer) | | | | | | | | Properties | | |
|---|---|---|---|---|---|---|---|---|---|---|---|
| | | MAH- | | | | | | | Residual | Adhesion | |
| | PP | g-PP | POE | EVA | Epoxy | TPU | PPE | PC | Fusion Heat | to EVA | WVTR |
| Ex. | (1) | (CA-100) | (2) | (3) | (4) | (5) | (6) | (7) | (8) | (9) | (10) |
| 10 | 75 | 5 | 20 | | | | | | 56.5 | 25.3 | 1.0 |
| 11 | 65 | 5 | 20 | 10 | | | | | 49.1 | 23.3 | 1.1 |
| 12 | 65 | 5 | 10 | 20 | | | | | 52.2 | 21.0 | 1.1 |
| 13 | 73 | 5 | 20 | | 2 | | | | 67.3 | 45.5 | 1.3 |
| 14 | 70 | 5 | 20 | | 5 | | | | 50.6 | 65.3 | 1.05 |
| 15 | 65 | 5 | 20 | | 10 | | | | 43.9 | 94.7 | 1.05 |
| 16 | 65 | 5 | 20 | | | 10 | | | 48.2 | 78.8 | 0.90 |
| 17 | 65 | 5 | 20 | | | | 10 | | 47.4 | 60.2 | 1.15 |
| 18 | 65 | 5 | 20 | | | | | 10 | 46.7 | 65.8 | 2.20 |

(1) HA748L polypropylene
(2) ENGAGE 8180
(3) EVA 14-2
(4) EPON-1009
(5) ISO-PLAST 202EZ
(6) Polyphenylene Ether (NORYL 731S)
(7) Polycarbonate (LEXAN 121)
(8) Residual fusion heat after lamination at 150° C. in J/g
(9) Adhesion to fast-cure EVA (FIRST EVA, F806) in N/cm
(10) Backsheet WVTR (in g/m2/day, 0.4 mm thickness, 38° C., 100% relative humidity)

Referring back to Table 2, of those tested examples, applicants have found that the most favorable combination of bonding strength and heat resistance properties is achieved with epoxy, thermoplastic polyurethane, polyphenylene ether, and polycarbonate. In contrast, applicants were unable to achieve sufficient bonding using only compatilizers and EVA. The manufacturing processes used for Table 1 examples were used for the Table 2 examples as well.

While the use of polypropylene polymer is preferred in accordance with the present invention, it is contemplated that a combination of high residual fusion heat after lamination and suitable adhesion to EVA can also be achieved through the use other thermoplastic olefins, such as polymethylpentene (PMP), and ethylene vinyl alcohol copolymer (EVOH) in conjunction with the second polymers (e.g., polyamide, epoxy, thermoplastic polyurethane (TPU), polyphenylene ether, and polycarbonate) set forth in the previous embodiments. Preferably, a backsheet layer containing such other thermoplastic olefins would contain at least 35 wt % of those thermoplastic olefins; however, preferably, higher amounts such as 50 wt %, 65 wt %, or 70 wt % could be used in conjunction with a second polymer to obtain sufficient residual fusion heat after lamination at 150° C. and sufficient bonding to EVA. To achieve such bonding strength, a layer preferably contains at least 5 wt % of the second polymer (e.g., polyamide, epoxy, thermoplastic polyurethane (TPU), polyphenylene ether, and polycarbonate), and more preferably at least 20 wt % of the second polymer; however, it is contemplated that only a small amount of the second polymer, such as 1 or 2 wt %, can achieve adequate bonding for certain applications. Preferably, the residual fusion heat after lamination at 150° C. is at least 40 J/g and bonding adhesion to EVA is greater than about 40 N/cm. More preferably, a backsheet layer using such other thermoplastic olefins has an even higher residual fusion heat after lamination, for example, 50 J/g or higher and/or a higher adhesion to EVA, such as at least 60 N/cm, or even more preferably, at least 80 N/cm.

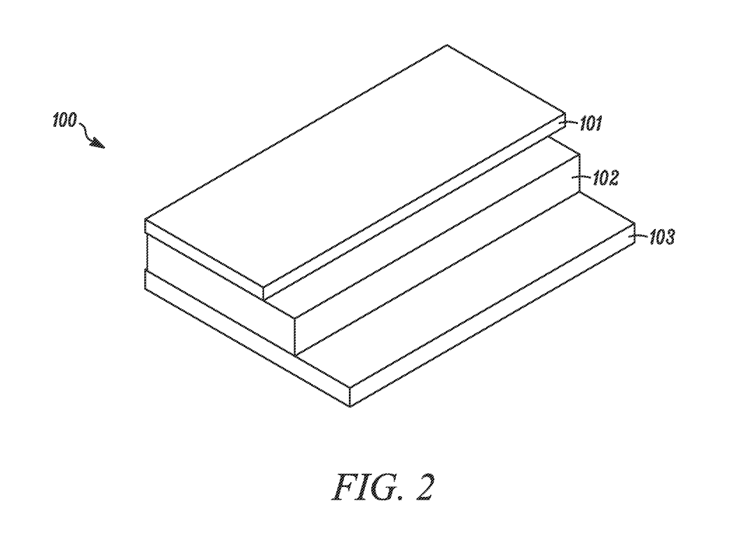

In accordance with the preceding embodiments, a single layer intended to be laminated to an EVA encapsulated photovoltaic module preferably has a thickness of 20-500 microns, and more preferably, between 20-100 microns. However, in accordance with a fifth embodiment of the present invention, a backsheet comprises other layers in addition to a first exterior layer corresponding to any of the preceding embodiments. A backsheet can have any suitable number of layers, including for example, the three-layer structure illustrated in FIG. 2. As shown in FIG. 2, a backsheet 100 includes a first exterior layer 101, an interior layer 102, and a second exterior layer 103. The backsheet 100 can be made utilizing any suitable equipment, including, for example, a laminator or an extruder. Layers can be sized based on the needs of a particular application. In one preferred three-layer embodiment, layer 101 is 20-100 microns in thickness, layer 102 is 100-300 microns in thickness, and layer 103 is 20-100 microns in thickness. Preferably, each of these layers contain the same TPO, such that the layers can be co-extruded without the use of tie layers or adhesive layers for adequate bonding. Alternatively, if needed, tie layers or adhesive layers can be used between layers. For example, if a barrier layer is used with the TPO layer of the first embodiment, a tie layer or an adhesive layer may be used.

In accordance with a sixth embodiment of the present invention, the backsheet layer and/or composite backsheets of the preceding embodiments may contain a number of additives, including, but not limited to compatibilizers, fillers, pigments, UV additives, flame retardants, etc. Examples of these include: polyolefin copolymer or elastomer, maleic anhydride (MAH) grafted olefin polymers, glass fiber, mica, carbon fibers, glass beads, TiO₂, antioxidants, heat stabilizers, UV screeners and absorbers. For example, in one preferred embodiment: a first exterior layer 101 comprises polypropylene, polyamide, compatilizers, and white pigment; a first interior layer 102 comprises polypropylene and filler; and, a second exterior layer 103 comprises polypropylene and UV additives.

In accordance with a seventh embodiment of the present invention, a backsheet in accordance with the preceding embodiments is laminated, or otherwise bonded, to an encapsulated photovoltaic module using methods which are known to persons skilled in the relevant art. Preferably, the encapsulant is an EVA encapsulant, and more preferably a fast-cure EVA encapsulant (e.g., FIRST EVA, F806), but other types of encapsulants may be used as well, provided that sufficient bonding strength (e.g., 40 N/cm) can be achieved.

In accordance with an eighth embodiment of the present invention, at least one layer of a TPO-containing composite backsheet is a weatherable fluoropolymer, e.g., a formulated thermoplastic polyolefin (TPO) as main substrate, protected with a layer of weatherable fluoropolymer. Example fluoropolymers include PVDF, ECTFE, PVF, THV, ETFE, FEP, and PCTFE. Preferably, a polypropylene based TPO is co-extruded with such fluoropolymers using a tier layer, laminated with such fluoropolymer films using adhesives, or coated with such fluoropolymer primers. A fluoropolymer film or coating layer can be either commercially sourced from the marketplace, or prepared using a film extrusion process.

Preferably, the fluoropolymer is white pigmented (with, e.g., titanium dioxide) to block UV light transmission.

A number of different backsheet samples were obtained or prepared, then tested using an accelerated aging test method (121 degree C., 100% humidity, 1 atm). The backsheet samples except a TPO-ECTFE laminate were sourced commercial products from the marketplace, with a typical PET (polyethylene terephthalate) thickness of 250 microns, and a white fluoropolymer layer having a typical thickness of 25-37 microns. The TPO-ECTFE backsheet sample was prepared by laminating a white pigmented ECTFE film (ethylene-chlorotrifluoroethylene copolymer) to the extruded TPO film layer with a polyurethane type crosslinking adhesive. The ECTFE film thickness was 19 microns. Test results are shown in Table 3 below:

TABLE 3

| | Visual Assessment after Pressure Cooker Test | | | |
|---|---|---|---|---|
| | (Test condition 121 degree C., 100% humidity, 1 atm) | | | |
| | Aging 24 | Aging 48 | Aging 72 | Aging 240 |
| Structure | hours | hours | hours | hours |
| PVF-PET-PVF | brittle | Brittle and | Cracked | x |
| Laminate | | bubble | | |
| PVDF-PET- | brittle | Brittle and | Cracked | x |
| EVA Laminate | | bubble | | |
| PET-PET-EVA | Intact | Brittle | easy | x |
| Laminate | | | cracking | |
| Double sided | brittle | Brittle and | Cracked | x |
| Fluoropolymer | | bubble | | |
| coating on PET | | | | |
| substrate | | | | |
| Fluoropolymer | brittle | Brittle and | Cracked | x |
| coating on | | bubble | | |
| PET/EVA | | | | |
| laminate | | | | |
| TPO-ECTFE | Intact and | Intact and | Intact and | Intact and |
| Laminate | flexible | flexible | flexible | flexible |

Different fluoropolymer films were tested for adhesion to a TPO layer. As shown in Table 4 below, with appropriate surface treatment, various fluoropolymer films can be readily laminated with TPO layers, which a sufficient bonding strength above 4 N/cm.

TABLE 4

| Laminate | Fluoropolymer | | Film surface | Interlayer |
|---|---|---|---|---|
| Sample | Film | Adhesive | Corona | bonding |
| Code | Type | Type ⁽¹⁾ | Treatment ⁽²⁾ | (N/CM) |
| ECTFE- | ECTFE | Thermal | In line treated | 7.2 |
| TPO ⁽³⁾ | | curing | 52 dyne | |
| PVDF- | PET-PET-EVA | Thermal | Off line treated | 4.5 |
| TPO ⁽⁴⁾ | Laminate | curing | 42 dyne | |
| PVDF- | Double sided | Thermal | Non treatment | 0.4 |
| TPO | Fluoropolymer | curing | | |
| | coating on PET | | | |
| | substrate | | | |
| ETFE- | Fluoropolymer | Thermal | Off line treated | 4.1 |
| TPO ⁽⁵⁾ | coating on | curing | 42 dyne | |
| | PET/EVA | | | |
| | laminate | | | |
| ETFE- | TPO-ECTFE | Thermal | Non treatment | 0 |
| TPO | Laminate | curing | | |

⁽¹⁾ Adhesive uses a polyester polyol system, and isocyanate as a crosslinker.
⁽²⁾ Both interfaces treatment.
⁽³⁾ TPO is referring to a formulated thermoplastic polyolefin film, ECTFE film is Honeywell E1250PW
⁽⁴⁾ PVDF film is made from Arkema Kynar ® resin.
⁽⁵⁾ ETFE is AGC Fluon ® ETFE FILM.

From the foregoing, it will be appreciated that although specific examples have been described herein for purposes of illustration, various modifications may be made without deviating from the spirit or scope of this disclosure. It is therefore intended that the foregoing detailed description be regarded as illustrative rather than limiting, and that it be understood that it is the following claims, including all equivalents, that are intended to particularly point out and distinctly claim the claimed subject matter.

What is claimed is:

1. A backsheet for a photovoltaic module having a first exterior layer, said first exterior layer comprising:
at least 35 wt % thermoplastic olefin polymer selected from the group consisting of polypropylene, polymethylpentene (PMP), and ethylene vinyl alcohol copolymer (EVOH); and,
at least 2 wt % of a second polymer,
wherein said first exterior layer has a residual fusion heat after lamination at 150° C. of at least 40 J/g.

2. The backsheet of claim 1, wherein the thermoplastic olefin polymer is polypropylene, and the second polymer is a polyamide or a mixture of polyamides.

3. The backsheet of claim 1, wherein said first exterior layer has a residual fusion heat after lamination at 150° C. of at least 50 J/g.

4. The backsheet of claim 1, wherein said backsheet comprises at least two layers, such that said backsheet comprises a second exterior layer on the opposite side of said backsheet from said first exterior layer.

5. The backsheet of claim 4, wherein said second exterior layer is co-extruded with said first exterior layer.

6. The backsheet of claim 5, wherein the second exterior layer comprises a fluoropolymer.

7. The backsheet of claim 5, wherein the thermoplastic olefin polymer in said first external layer is present in each additional layer of the backsheet, such that the backsheet layers are chemically affinitive, and therefore require no tie layers or extra adhesive layers between them.

8. The backsheet of claim 4, wherein at least a first interior layer is used to bond the first exterior layer to a second exterior layer.

9. The backsheet of claim 4, wherein the second exterior layer comprises a fluoropolymer.

10. The backsheet of claim 9, wherein the fluoropolymer is an ethylene-chlorotrifluoroethylene copolymer.

11. The backsheet of claim 1, wherein said first exterior layer comprises at least 65 wt % polypropylene polymer.

12. The backsheet of claim 1, wherein the first exterior layer is 20-100 microns in thickness.

13. The backsheet of claim 1, wherein said first exterior layer has a bonding adhesion to EVA of greater than about 40 N/cm after lamination to the EVA at a temperature of about 140-150° C.

14. The backsheet of claim 10, wherein the second polymer is selected from the group consisting of epoxy, thermoplastic polyurethane, polyphenylene ether, and polycarbonate.

15. The backsheet of claim 1, wherein the first exterior layer comprises at least 5 wt % of said second polymer.

16. A photovoltaic module comprising a backsheet according to claim 1.

17. A method of manufacturing a layer for use in a backsheet for a photovoltaic module, said method comprising the steps of:
blending a thermoplastic olefin polymer selected from the group consisting of polypropylene, polymethylpentene (PMP), and ethylene vinyl alcohol copolymer (EVOH), and a second polymer selected from the group consisting of polyamide, epoxy, thermoplastic polyurethane, polyphenylene ether, and polycarbonate; and,
extruding the thermoplastic olefin polymer and the second polymer to form a backsheet having a first exterior layer configured to be bonded to the photovoltaic module, said first exterior layer comprising:
at least 35 wt % thermoplastic olefin polymer; and,
at least 2 wt % of the second polymer,
wherein the layer has a residual fusion heat after lamination at 150° C. of at least 40 J/g.
